(19) United States
(12) Patent Application Publication
(10) Pub. No.: US 2022/0208808 A1
(43) Pub. Date: Jun. 30, 2022

(54) IMAGE SENSING DEVICE

(71) Applicant: SK hynix Inc., Icheon-si (KR)

(72) Inventor: Pyong Su KWAG, Icheon-si (KR)

(21) Appl. No.: 17/329,492

(22) Filed: May 25, 2021

(30) Foreign Application Priority Data
Dec. 29, 2020 (KR) 10-2020-0186525

(51) Int. Cl. H01L 27/146

(52) U.S. Cl. CPC H01L 27/1463; H01L 27/14623; H01L 27/14627; H01L 27/14643

(57) ABSTRACT

An image sensing device may include a base substrate; a pixel array supported by the base substrate and structured to include a plurality of image sensing pixels responsive to light to produce pixel signals and a guard ring region arranged in a region outside a first surface of the pixel array; a plurality of first conductive type isolation layers formed in the base substrate from a first surface of the guard ring region to a first depth in the base substrate; at least one second conductive type isolation layer formed in the base substrate from the first surface of the guard ring region to a second depth in the base substrate and positioned between the first conductive type isolation layers; and a first isolation layer formed in the base substrate from a second surface of the guard ring region to a third depth in the base substrate, the first isolation layer extending to the first conductive type isolation layer and the second conductive type isolation layer adjacent to each other.

### CROSS-REFERENCES TO RELATED APPLICATION

This patent document claims the priority and benefits of Korean application number 10-2020-0186525, filed on Dec. 29, 2020, which is incorporated herein by reference in its entirety.

### TECHNICAL FIELD

The technology and implementations disclosed in this patent document generally relate to an image sensing device.

### BACKGROUND

Imaging pixels of image sensors such as a CMOS image sensor (CIS) may capture light and convert it into electrical signals. For example, the imaging pixels convert, into an electrical signal, an electric potential difference caused by electrons that are generated based on photons incident on a photodiode.

The imaging pixels may be isolated from each other. The photons detected by each isolated imaging pixel may be converted into voltages, and the voltages are combined to represent an image.

In recent years, the increase in the resolution of CMOS image sensors has led to the decrease in the pixel size. In this trend, one of the challenges is the need to suppress the optical and electrical crosstalk between adjacent imaging pixels. Many pixel isolation architectures have been proposed to suppress the optical and electrical crosstalk.

### SUMMARY

The technology disclosed in this patent document can be implemented in various embodiments to provide an image sensing device that may reduce the crosstalk between imaging pixels in a pixel array.

In some embodiments of the disclosed technology, an image sensing device may include a base substrate, a pixel array supported by the base substrate and structured to include a plurality of image sensing pixels responsive to light to produce pixel signals and a guard ring region arranged in a region outside a first surface of the pixel array, a plurality of first conductive type isolation layers formed in the base substrate from a first surface of the guard ring region to a first depth in the base substrate, at least one second conductive type isolation layer formed in the base substrate from the first surface of the guard ring region to a second depth in the base substrate and positioned between the first conductive type isolation layers, and a first isolation layer formed in the base substrate from a second surface of the guard ring region to a third depth in the base substrate, the first isolation layer extending to the first conductive type isolation layer and the second conductive type isolation layer adjacent to each other.

In some embodiments of the disclosed technology, a junction isolation and a back deep trench isolation (BDTI) may be connected with each other to prevent noises from infiltrating into the pixel array.

In some embodiments of the disclosed technology, an image sensing device may include a base substrate, a plurality of first conductive type isolation layers, at least one second conductive type isolation layer and a first isolation layer. The base substrate may include a pixel array and a guard ring arranged in a peripheral region fiducially a first surface of the pixel array. The first conductive type isolation layers may be inserted into a first surface of the guard ring in a depth direction. The second conductive type isolation layer may be inserted into the first surface of the guard ring in the depth direction. The second conductive type isolation layer may be positioned between the first conductive type isolation layers. The first isolation layer may be inserted into a second surface of the guard ring in the depth direction. The first isolation layer may be extended to the first conductive type isolation layers and the second conductive type isolation layer. The first isolation layer may be inserted into the first conductive type isolation layers and the second conductive type isolation layer.

### BRIEF DESCRIPTION OF THE DRAWINGS

FIG. 1 illustrates an example of a pixel array of an image sensing device based on example embodiments of the disclosed technology.

FIG. 2 illustrates an example of the pixel array and a guard ring region illustrated in FIG. 1.

FIGS. 3A and 3B illustrate cross-sectional views of FIG. 2 based on example embodiments of the disclosed technology.

FIGS. 4A and 4B illustrate cross-sectional views of FIG. 2 based on example embodiments of the disclosed technology.

FIGS. 5A and 5B illustrate examples of an isolation layer based on example embodiments of the disclosed technology.

FIG. 6 illustrates an imaging device using an image sensing device based on example embodiments of the disclosed technology.

FIG. 7 illustrates an image sensing device based on example embodiments of the disclosed technology.

FIG. 8 illustrates an electronic device based on example embodiments of the disclosed technology.

### DETAILED DESCRIPTION

Features of the technology disclosed in this patent document are described by examples of an image sensing device with reference to the accompanying drawings.

Although a few embodiments of the disclosed technology will be discussed, the disclosed technology can be implemented in various ways beyond the specifics of the examples described herein.

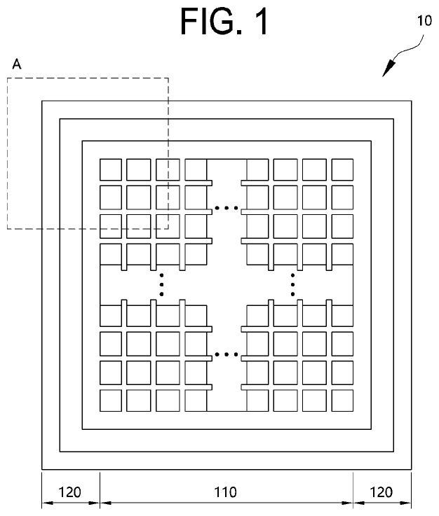

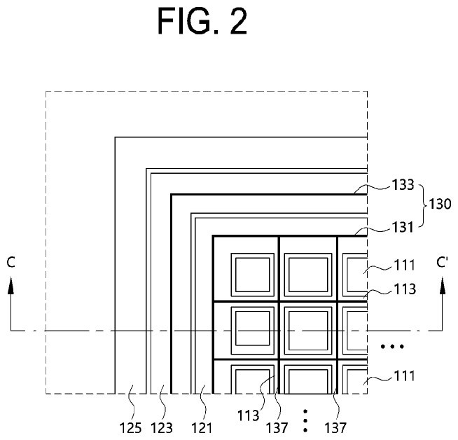

FIG. 1 illustrates an example of a pixel array of an image sensing device based on example embodiments of the disclosed technology. FIG. 2 illustrates the pixel array and a guard ring region in FIG. 1.

Hereinafter, a pixel array and a guard ring in FIG. 1 will be discussed in detail with reference to FIG. 2. FIG. 2 shows in detail a region “A” in FIG. 1.

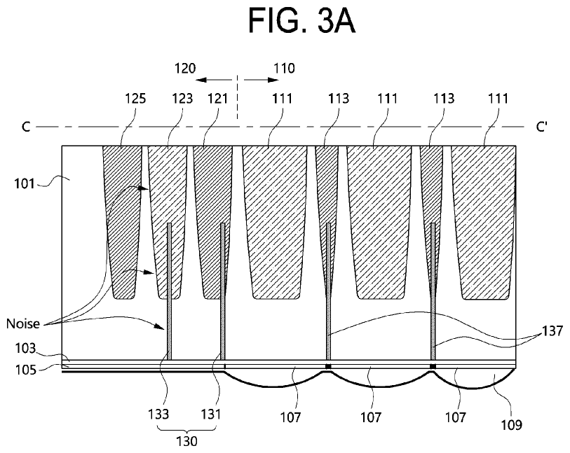

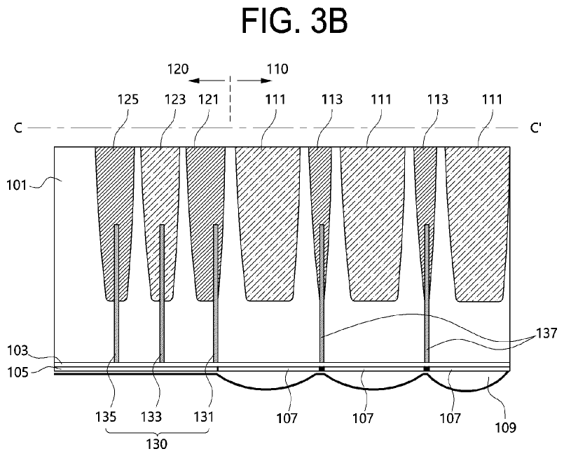

Referring to FIGS. 1 and 3A, an image sensing device 10 may include a base substrate 101. The base substrate 101 may be structured to include a pixel array region for supporting a pixel array 110 and a guard ring region 120 for supporting one or more guard rings.

The pixel array 110 may include a plurality of image sensing pixels and each image sensing pixel responds to light to produce an electrical signal as the pixel signal representing the light detected by that pixel. The image sensing pixels may be isolated from each other. Each of the image sensing pixels may include a photo-detection element that converts light into photocharge and may be implemented in various configurations including, for example, a photodiode.

In some implementations, the image sensing device 10 may further include a peripheral circuit (not shown) arranged to surround the guard ring region 120. The peripheral circuit may be electrically connected to the pixel array 110. The peripheral circuit may include various circuits and configured to control the pixel array 110. For example, the peripheral circuit may include a plurality of transistors configured to provide electrical signals to a photodetector (e.g., photodiode) of each of the image sensing pixels arranged in the pixel arrays 110. The transistors of the peripheral circuit may receive and process electrical signals from the image sensing pixels. For example, the peripheral circuit may include logic circuits such as a timing generator, a row decoder, a row driver, a correlated double sampler (CDS), an analog to digital converter (ADC), and a column decoder.

Referring to FIG. 3A, the base substrate 101 may include regions in which the pixel array 110 and the guard ring region 120 are formed. The guard ring region 120 may be formed in a region outside a first surface of the pixel array 110. A guard ring can be formed in the guard ring region 120 to electrically or optically isolate or protect the pixel array from noise.

The base substrate 101 may include a photo sensing region which may be, for example, a photodiode region. The photodiode region may include a photodiode to convert light into photocharge carried by an electrical current. The photocharge is accumulated at a certain region that is connected to the photodiode.

The pixel array 110 may include a first conductive type diode region 111, a second conductive type isolation layer 113 and a second isolation layer 137. The first conductive type diode region is a region of a diode that includes a first conductive type impurity (e.g., a p-doped region), and the second conductive type diode region is a region of a diode that includes a second conductive type impurity (e.g., an n-doped region). The interface region of those two regions forms a p-n junction which converts light into photocharge.

The first conductive type diode region 111 may be formed in the base substrate 101 from the first surface of the pixel array 110 to a certain depth in the base substrate 101. In some implementations, a plurality of photodiodes may be formed in the first conductive type diode region 111.

The second conductive type isolation layer 113 may be formed in the base substrate 101 from the first surface of the pixel array 110 to a certain depth in the base substrate 101. The second conductive type isolation layer 113 may be positioned between adjacent first conductive type diode regions 111. The second conductive type isolation layer 113 may include a plurality of isolation layers. For example, as shown in FIGS. 3A and 3B, the first conductive type diode region 111 and the second conductive type isolation layer 113 may be alternately arranged.

The second isolation layer 137 may be formed in the base substrate 101 from a second surface of the pixel array 110 to a certain depth in the base substrate 101, extending to the second conductive type isolation layer 113. The second isolation layer 137 may be formed such that an end of the second isolation layer 137 is inserted into or in contact with the second conductive type isolation layer 113. The second isolation layer 137 may include a plurality of isolation layers.

As shown in FIGS. 3A and 3B, each of the second isolation layers 137 may be formed such that an end of each second isolation layer 137 is inserted into or in contact with one of the second conductive type isolation layers 113 to shield the first surface and the second surface of the pixel array 110.

The second isolation layer 137 may include a back deep trench isolation (BDTI).

In an implementation, referring to FIGS. 3A and 3B, the first conductive type diode region 111 may include an N type diode region. The second conductive type isolation layer 113 may include a P type isolation layer. That is, the base substrate 101 in FIGS. 3A and 3B may have a CIS pixel structure including a P type base substrate and an N type impurity region that is formed in the P type base substrate to form a P-N junction.

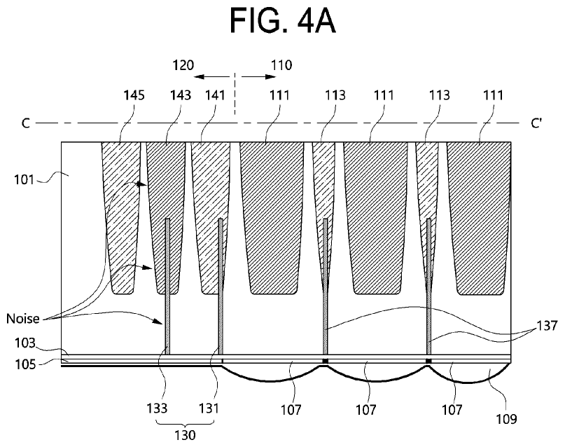

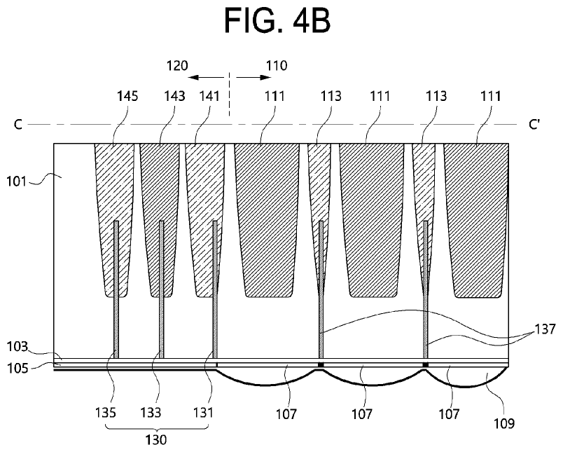

In another implementation, referring to FIGS. 4A and 4B, the first conductive type diode region 111 may include a P type diode region. The second conductive type isolation layer 113 may include an N type isolation layer. That is, the base substrate 101 in FIGS. 4A and 4B may have a CIS pixel structure including an N type base substrate and a P type impurity region that is formed in the N type base substrate to form a P-N junction.

As mentioned above, the first conductive type and the second conductive type may be either P type or N type. The first conductive type may be either N type or P type, and the second conductive type may be either P type or N type.

Referring to FIG. 2, the guard ring region 120 may include first conductive type isolation layers 121 and 125, a second conductive type isolation layer 123 and first isolation layers 130, 131 and 133.

FIGS. 3A and 3B illustrate cross-sectional views of FIG. 2 based on example embodiments of the disclosed technology.

Referring to FIGS. 3A and 3B, the first conductive type isolation layers 121 and 125 may be formed in the base substrate 101 from a first surface of the guard ring 120 to a certain depth in the base substrate 101. The first conductive type isolation layers 121 and 125 may include a plurality of isolation layers. The base substrate 101 in FIGS. 3A and 3B may have the CIS pixel structure including the N type impurity region formed on the P type base substrate.

The second conductive type isolation layer 123 may be formed in the base substrate 101 from the first surface of the guard ring 120 to a certain depth in the base substrate 101. The second conductive type isolation layer 123 may be positioned between the first conductive type isolation layers 121 and 125. The second conductive type isolation layer 123 may include at least one isolation layer.

The first isolation layers 130 (131, 133, 135) may be formed in the base substrate 101 from a second surface of the guard ring 120 to a certain depth in the base substrate 101, extending to the adjacent first conductive type isolation layers 121 and 125 and the second conductive type isolation layer 123. The first isolation layers 131, 135, 133 may be formed such that ends of the first isolation layers are inserted into or in contact with the first conductive type isolation layers 121 and 125 and the second conductive type isolation layer 123, respectively.

Referring to FIGS. 3A and 3B, the first conductive type isolation layers 121 and 125 may be a P type isolation layer. The second conductive type isolation layer 123 may be an N type isolation layer.

Referring to FIG. 3A, the first conductive type isolation layer 121, the at least one second conductive type isolation layer 123, and the first conductive type isolation layer 125 may be arranged in a direction away from the pixel array 110. For example, a first P type isolation layer 121, an N type isolation layer 123 and a second P type isolation layer 125 are arranged in a direction away from the pixel array 110.

In some implementations, the first isolation layers 131 and 133 may be formed such that ends of the first isolation layers 131 and 133 are inserted into or in contact with the first P type isolation layer 121 and the N type isolation layer 123, respectively.

As shown in FIG. 3A, the image sensing device 10 may include a lower portion where the first isolation layer 133 is formed and an upper portion where the N type isolation layer 123 is connected to the first isolation layer 133. In some implementations, the first isolation layer 133 is connected to the N type isolation layer 123 such that one end of the first isolation layer 133 is inserted into or in contact with the N type isolation layer 123, thereby preventing noises from entering the imaging pixels.

In some implementations, the first isolation layer 133 extends from the second surface of the guard ring region 120 toward the lower portion of the substrate. In some implementations, the N type isolation layer 123 extends from the first surface of the guard ring region 120 toward the upper portion of the substrate.

In some implementations, the N type isolation layer 123 may include N type junction isolation layer and the first isolation layer 133 may include BDTI may be formed in a same region of the guard ring region 120 to block the infiltration of the noises.

In some implementations, referring to FIG. 3B, the first isolation layers 131, 133 and 135 may be formed such that ends of the first isolation layers 131, 133 and 135 are inserted into or in contact with the first P type isolation layer 121, the N type isolation layer 123 and the second P type isolation layer 125, respectively.

FIGS. 4A and 4B illustrate cross-sectional views of FIG. 2 based on example embodiments of the disclosed technology.

Referring to FIGS. 4A and 4B, each of first conductive type isolation layers 141 and 145 may include an N type isolation layer. A second conductive type isolation layer 143 may include a P type isolation layer.

In some implementations, the first conductive type isolation layer 141, the at least one second conductive type isolation layer 143 and the first conductive type isolation layer 145 may be arranged in a direction away from the pixel array 110. For example, a first N type isolation layer 141, a P type isolation layer 143 and a second N type isolation layer 145 are arranged in a direction away from the pixel array 110. The base substrate 101 in FIGS. 4A and 4B may have the CIS pixel structure including the P type impurity region formed on the N type base substrate.

In an implementation, referring to FIG. 4A, the first isolation layers 131 and 133 may be formed such that ends of the first isolation layers 131 and 133 are inserted into or in contact with the first N type isolation layer 141 and the P type isolation layer 123, respectively.

In another implementation, referring to FIG. 4B, the first isolation layers 131, 133 and 135 may be formed such that ends of the first isolation layers 131, 133 and 135 are inserted into or in contact with the first N type isolation layer 141, the P type isolation layer 143 and the second N type isolation layer 145, respectively.

In some implementations, the first isolation layers 130, 131, 133 and 135 may include BDTI.

The first isolation layers 130, 131, 133 and 135 may be structured to electrically or optically separate the guard ring region 120 from the pixel array 110. The first isolation layers 130, 131, 133 and 135 may prevent an electrical or optical crosstalk, thereby improving a signal-to-noise ratio.

Further, the first isolation layers 130, 131, 133 and 135 may be formed by doping a material having a high reflectivity to light. Thus, the first isolation layers 130, 131, 133 and 135 may prevent light from propagating in unwanted directions toward the pixel array 110, thereby reducing an optical crosstalk.

Referring to FIG. 3A, the image sensing device 10 may include a planarization layer 103, a light shielding layer 105, a color filter 107 and a lens 109. The planarization layer 103 may include an electrically insulating material.

The color filter 107 may be formed on a region of a surface of the base substrate 101 corresponding to an image sensing pixel of the pixel array 110.

As shown in FIG. 3A, the color filter 107 may selectively transmit light at a specific wavelength, and may include a red color filter, a green color filter, a blue color filter, a magenta color filter and a yellow color filter.

The light shielding layer 105 may be formed on a region of the surface of the base substrate 101 corresponding to the guard ring region 120.

When light is incident on a light receiving layer (not shown), the light shielding layer 105 may shield the device from incident light. In an implementation, the light shielding layer 105 may include tungsten. The light receiving layer may indicate layers from the lens 109 to an upper layer of the base substrate 101.

The lens 109 may be formed on the color filter 107. The lens 109 may be used to focus the incident light onto a center of the pixel array 110. The lens 109 may include a micro lens.

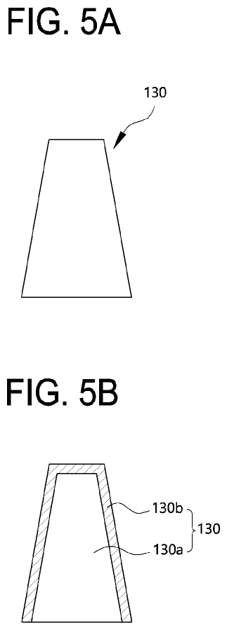

FIGS. 5A and 5B illustrate examples of an isolation layer based on example embodiments of the disclosed technology.

Referring to FIG. 5A, the first isolation layers 131, 133 and 135 and the second isolation layer 137 illustrated in FIGS. 3A, 3B, 4A and 4B may include an insulation material.

In some implementations, the isolation layer 130 may include a single insulation material layer having a high dielectric constant. In some implementations, the isolation layer 130 may include a first insulation material layer 130a and a second insulation material layer 130b formed at a surface of the first insulation material 130a. The second insulation material layer 130b has a higher dielectric constant than the first insulation material layer 130a.

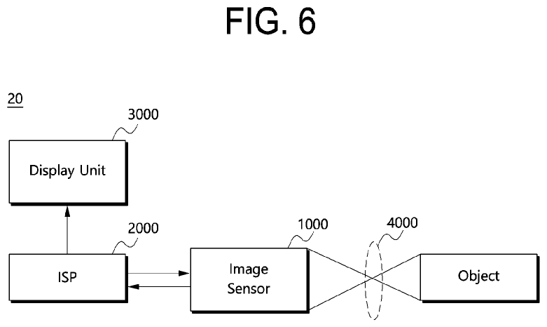

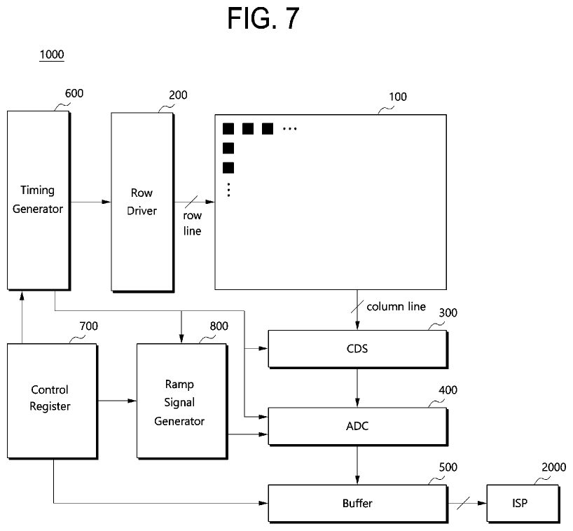

FIG. 6 illustrates an imaging device using an image sensing device based on example embodiments of the disclosed technology.

Referring to FIG. 6, an electronic device 20 may include an image sensing device 1000, an image signal processor (ISP) 2000 and a display unit 3000. The electronic device 20 may include a digital camera, a portable electronic device with a digital camera, for example, a cellular phone, a smart phone, and a tablet person computer.

The image sensing device 1000 may include a CMOS image sensor. The image sensing device 1000 may capture light reflected from an object through a lens 4000, and the image signal processor 2000 can control the operations of the image sensing device 1000. The image sensing device 1000 may generate image data based on the captured light and provide the image data to the image signal processor 2000. The image signal processor 2000 may process the image signal generated by the image sensing device 1000 and transmit digital image data signals to the display 3000.

The image sensing device 1000 and the image signal processor 2000 may include a printed circuit board (PCB) such as a motherboard, an integrated circuit (IC), and a system on chip (SoC). In example embodiments, the image sensing device 1000 and the image signal processor 2000 may be incorporated into one package such as a multi-chip package (MIP) and a system in package (SiP). The image sensing device 1000 may include a CMOS image sensor chip.

FIG. 7 illustrates an image sensing device based on example embodiments of the disclosed technology.

Referring to FIG. 7, an image sensing device 1000 may include a pixel array 100, a row driver 200, a correlated double sampler (CDS) 300, an analog-digital converter (ADC) 400, a buffer 500, a timing generator 160, a control register circuit 700 and a ramp signal generator 800.

The pixel array 100 may include an active pixel region, an optical black pixel region and a dummy region. Active pixels APX may be formed in the active pixel region. Optical black pixels OBPX may be formed in the optical black pixel region.

Active pixels APX may be connected to row lines and column lines, which are used to select at least one of the active pixels APX. Each of the active pixels APX may generate an electrical signal (active signal) corresponding to the light captured by the active pixels APX. That is, each of the active pixels APX may convert optical signals representing captured images into the electrical signal to output an electrical image signal to the CDS 300 through the column lines. The active pixels APX may include a photodetector such as a photodiode, a pinned photodiode, and a photo gate.

Each of the active pixels APX may have the structure illustrated in FIGS. 3A, 3B, 4A and 4B.

The optical black pixels (not shown) in the optical black pixel region (not shown) may be used to generate an electrical signal while shielding the incident light. The electrical signal generated by the optical black pixels may be an optical black signal having “dark level.” In some implementations, each of the optical black pixels OBPX may include the photo detector.

The control register circuit 700 may generate at least one control signal for controlling operations of the timing generator 600, the ramp signal generator 800 and the buffer 500.

The row driver 200 may activate the pixel array 1100 on a row by row basis. In some implementations, the row driver 200 may generate a row selection signal for selecting at least one of the rows in the pixel array 100.

In some implementations, each of the active pixels APX may detect the incident light to output the active signal to the CDS 300. In some implementations, each of the optical black pixels OBPX may output the optical black signal to the CDS 300.

CMOS image sensors may use the correlated double sampling (CDS) to remove an undesired offset value of pixels by sampling a pixel signal twice to remove the difference between these two samples. In one example, the correlated double sampling (CDS) may remove the undesired offset value of pixels by comparing pixel output voltages obtained before and after a light signal is incident on the pixels so that only pixel output voltages based on the incident light can be measured. In some implementations of the disclosed technology, the CDS 300 may perform correlated double sampling using the received active signal and the optical black signal.

In example embodiments, the CDS 300 may hold and sample a reference voltage level and a voltage level of the received electrical image signal. The CDS 300 may then transmit an analog signal corresponding to a difference between the reference voltage level and the voltage level of the electrical image signal to the ADC 400.

The ADC 400 is used to convert analog CDS signals to digital signals. Examples of the ADC 400 may include a ramp-compare type ADC where the analog pixel signal is compared with a reference signal such as a ramp signal that ramps up or down and a timer counts until a voltage of the ramp signal matches the analog pixel signal. In some implementations of the disclosed technology, the ADC 400 may compare a ramp signal generated by the ramp signal generator 800 with a correlated-double-sampled signal generated by the CDS 300 to output a plurality of comparison signals. The ADC 400 may transmit count values obtained by counting the number of transitions of the comparison signals in response to a clock signal to the buffer 500.

The buffer 500 may temporarily store the count value, i.e., the digital active signals generated by the ADC 400. The buffer 500 may sense, amplify and output the digital active signals. The digital active signals held by the buffer 500 may include the dark current caused by the photodetector.

The image signal processor (ISP) 2000 may adjust an offset value of the digital image signal transmitted from the buffer 500 of the image sensing device 1000 based on the dark level correction value and a correction coefficient.

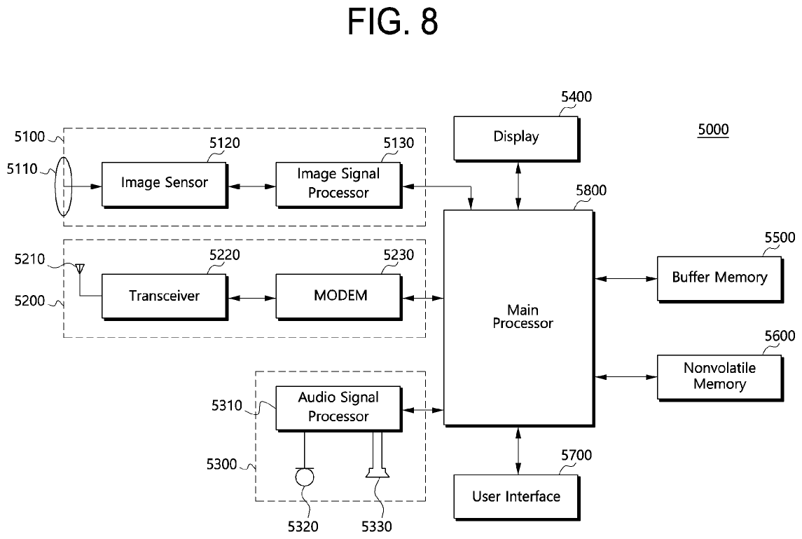

FIG. 8 illustrates an electronic device based on example embodiments of the disclosed technology.

Referring to FIG. 8, an electronic device 5000 may include an image processor 5100, a communication device 5200, an audio processor 5300, a display device 5400, a buffer memory 5500, a non-volatile memory 5600, a user interface 5700 and a main processor 5800.

The image processor 5100 may receive an optical signal through a lens 5110. An image sensing device 5120 and an image signal processor 5130 in the image processor 5100 may generate image data representing an object based on the received optical signal. For example, the image sensing device 5120 and the image signal processor 5130 may have functions that are identical or similar to those of the image sensor and the image signal processor in FIGS. 6 and 7.

The communication device 5200 may exchange signals with an external device through an antenna 5210. A transmitter/receiver 5220 and a MODEM 5230 in the communication device 5200 may process the signal communicated with the external device based on various wireless communication protocols or rules.

The audio processor 5300 may process an audio signal using an audio signal processor 5310. The audio processor 5300 may receive the audio signal through a microphone 5320 to digitally process the audio signal. The audio processor 5300 may regenerate the audio signal to output the regenerated audio signal through a speaker 5330.

The display device 5400 may receive data from the external device such as the main processor 5800. The display device 5400 may display an image through a display panel based on the received data.

The buffer memory 5500 may store data used for operations of the electronic device 5000. The buffer memory 5500 may temporarily store data processed or to be processed by the main processor 5800. For example, the buffer memory 5500 may include a volatile memory such as a static random access memory (SRAM), a dynamic RAM (DRAM), a synchronous DRAM (SDRAM), etc., a non-volatile memory such as a phase-change RAM (PRAM), a magneto-resistive RAM (MRAM), a resistive RAM (ReRAM), a Ferro-electric RAM (FRAM), etc.

The non-volatile memory 5600 may store data regardless of a supplying of a power. The non-volatile memory 5600 may include at least one of a flash memory, a PRAM, an MRAM, a ReRAM, an FRAM, etc. The non-volatile memory 5600 may include a detachable memory such as a secure digital (SD) card and/or an embedded memory such as an embedded multimedia card (eMMC).

The user interface 5700 may provide an interface to the communications between the user and the electronic device 5000. For example, the user interface 5700 may include an input interface such as a keypad, a button, a touch screen, a touch pad, a gyroscope, a vibration sensor, an acceleration sensor, etc. The user interface 5700 may include an output interface such as a monitor, an LED lamp, etc.

The main processor 5800 may control the operations of the electronic device 5000. The main processor 5800 may perform computations to operate the electronic device 5000. For example, the main processor 5800 may include at least one processor core such as a general-purpose processor, a special-purpose processor, an application processor, and a microprocessor.

Only limited examples of implementations or embodiments of the disclosed technology are described or illustrated. Variations and enhancements for the disclosed implementations or embodiments and other implementations or embodiments are possible based on what is disclosed and illustrated in this patent document.

What is claimed is:

1. An image sensing device comprising:
a base substrate;
a pixel array supported by the base substrate and structured to include a plurality of image sensing pixels responsive to light to produce pixel signals and a guard ring region arranged in a region outside a first surface of the pixel array;
a plurality of first conductive type isolation layers formed in the base substrate from a first surface of the guard ring region to a first depth in the base substrate;
at least one second conductive type isolation layer formed in the base substrate from the first surface of the guard ring region to a second depth in the base substrate and positioned between the first conductive type isolation layers; and
a first isolation layer formed in the base substrate from a second surface of the guard ring region to a third depth in the base substrate, the first isolation layer extending to the first conductive type isolation layer and the second conductive type isolation layer adjacent to each other.

2. The image sensing device of claim 1, wherein the first isolation layer comprises a back deep trench isolation (BDTI).

3. The image sensing device of claim 1, wherein the first isolation layer comprises an electrically insulating material.

4. The image sensing device of claim 1, wherein the first isolation layer comprises a material having a high dielectric constant.

5. The image sensing device of claim 1, wherein the first conductive type isolation layers comprise P type isolation layers and the second conductive type isolation layer comprises an N type isolation layer.

6. The image sensing device of claim 5, wherein the first conductive type isolation layers and the at least one second conductive type isolation layer include a first P type isolation layer, an N type isolation layer and a second P type isolation layer that are arranged in a direction away from the pixel array, and wherein the first isolation layer extends such that an end of the first isolation layer is inserted into or in contact with the first P type isolation layer and the N type isolation layer.

7. The image sensing device of claim 5, wherein the first conductive type isolation layers and the at least one second conductive type isolation layer include a first P type isolation layer, an N type isolation layer and a second P type isolation layer that are arranged in a direction away from the pixel array, and wherein the first isolation layer extends such that an end of the first isolation layer is inserted into or in contact with the first P type isolation layer, the N type isolation layer and the second P type isolation layer.

8. The image sensing device of claim 1, wherein the first conductive type isolation layers comprise N type isolation layers and the second conductive type isolation layer comprises a P type isolation layer.

9. The image sensing device of claim 8, wherein the first conductive type isolation layers and the at least one second conductive type isolation layer include a first N type isolation layer, a P type isolation layer and a second N type isolation layer that are arranged in a direction away from the pixel array, and wherein the first isolation layer extends such that an end of the first isolation layer is inserted into or in contact with the first N type isolation layer and the P type isolation layer.

10. The image sensing device of claim 8, wherein the first conductive type isolation layers and the at least one second conductive type isolation layer include a first N type isolation layer, a P type isolation layer and a second N type isolation layer that are arranged in a direction away from the pixel array, and wherein the first isolation layer extends such that an end of the first isolation layer is inserted into or in contact with the first N type isolation layer, the P type isolation layer and the second N type isolation layer.

11. The image sensing device of claim 1, wherein the pixel array comprises:
a plurality of first conductive type diode regions formed in the base substrate from a first surface of the pixel array to a depth in the base substrate; and
a plurality of second conductive type isolation layers formed in the base substrate from the first surface of the pixel array to a depth in the base substrate, wherein the second conductive type isolation layers are positioned between the first conductive type diode regions.

12. The image sensing device of claim 11, wherein the pixel array further comprises a second isolation layer formed in the base substrate from a second surface of the pixel array to a depth in the base substrate, and the second isolation layer extends such that an end of the second isolation layer is inserted into or in contact with the second conductive type isolation layers.

13. The image sensing device of claim 11, wherein the first conductive type diode region comprises an N type diode region, and the second conductive type isolation layer comprises a P type isolation layer.

14. The image sensing device of claim 11, wherein the first conductive type diode region comprises a P type diode region, and the second conductive type isolation layer comprises an N type isolation layer.

15. The image sensing device of claim 1, wherein the base substrate comprises a photodiode region.

16. The image sensing device of claim 1, further comprising:
a color filter formed on a region of a surface of the base substrate corresponding to the pixel array;
a light shielding layer formed on a region of a surface of the base substrate corresponding to the guard ring region; and
a lens formed on the color filter.
